(19) United States
(12) Patent Application Publication
(10) Pub. No.: US 2025/0253141 A1
(43) Pub. Date: Aug. 7, 2025

(54) PHOTOELECTRON SOURCE, MULTI-PHOTOELECTRON SOURCE AND MULTI-BEAM IRRADIATION APPARATUS

(71) Applicant: NuFlare Technology, Inc., Yokohama-shi (JP)

(72) Inventors: Munehiro OGASAWARA, Hiratsuka-shi (JP); Taku YAMADA, Ayase-shi (JP)

(73) Assignee: NuFlare Technology, Inc., Yokohama-shi (JP)

(21) Appl. No.: 19/008,101

(22) Filed: Jan. 2, 2025

(30) Foreign Application Priority Data
Feb. 7, 2024 (JP) 2024-017251
Nov. 11, 2024 (JP) 2024-196816

(51) Int. Cl. H01J 40/06; G02B 3/00; G02B 5/08; G02B 5/10; H01J 3/22

(52) U.S. Cl. CPC H01J 40/06; G02B 3/005; G02B 5/0808; G02B 5/10; H01J 3/22

(57) ABSTRACT

In one embodiment, a photoelectron source includes a photocathode supported on a surface side of a substrate, a light source emitting excitation light from a back surface side of the substrate, and a reflecting mirror disposed at a position opposed to the photocathode on the surface side of the substrate configured to reflect and focus the excitation light which has passed through the substrate to the photocathode and include an extraction hole through which photoelectrons emitted from the photocathode due to irradiation of the excitation light pass.

### CROSS REFERENCE TO RELATED APPLICATION

This application is based upon and claims benefit of priority from the Japanese Patent Application No. 2024-17251, filed on Feb. 7, 2024, and the Japanese Patent Application No. 2024-196816, filed on Nov. 11, 2024, the entire contents of which are incorporated herein by reference.

### FIELD

The present invention relates to a photoelectron source, a multi-photoelectron source and a multi-beam irradiation apparatus.

### BACKGROUND

In recent years, along with high integration of LSI, the circuit line width required for semiconductor devices has been reduced year by year. Here, the electron ray (electron beam) writing technique essentially has an excellent resolution, and a mask pattern is written to a mask blank with an electron beam.

For example, there is a writing apparatus using a multi-beam. Compared to a single electron beam writing, many beams can be irradiated at one time using a multi-beam, thus the throughput can be significantly improved. In a multi-beam writing apparatus, for example, an electron beam emitted from an electron gun is passed through a mask having a plurality of holes to form a multi-beam which is each blanking- controlled, and each beam not blocked by a limiting aperture is reduced by an optical system, a mask image is reduced, and deflected by a deflector, then applied to a desired position on a sample.

As an electron beam source, a technique has been discussed to form an electron beam by receiving irradiation of excitation light on the back surface (the upper surface) of a photocathode, and emitting electrons from the surface (the lower surface). In this case, the photocathode needs to be thin enough to allow the excitation light to reach the surface of the photocathode, therefore there is a problem in that the utilization efficiency of the excitation light is low.

A configuration has been proposed in which the surface of the photocathode is irradiated with excitation light, and electron beams are emitted from the surface of the photocathode. However, with the method of irradiating the surface of the photocathode with excitation light, implementation of multi-beam has been difficult.

### BRIEF DESCRIPTION OF THE DRAWINGS

FIG. 1 is a schematic view of a photoelectron source according to an embodiment of the present invention.

FIG. 2 is a schematic view of a photoelectron source according to another embodiment.

FIG. 3 is a plan view of a support plate.

FIG. 4 is a schematic view of a photoelectron source according to another embodiment.

FIG. 5 is a schematic view of a photoelectron source according to another embodiment.

FIG. 6 is a schematic view of a multi-photoelectron source.

FIG. 7 is a schematic view of a multi-photoelectron source according to a variant.

FIG. 8 is a schematic view of a multi-beam writing apparatus.

FIG. 9 is a schematic view of a multi-beam inspection apparatus.

FIG. 10 is a schematic view of a photoelectron source according to a variant.

FIG. 11 is a schematic view of a photoelectron source according to a variant.

FIG. 12 is a schematic view of a photoelectron source according to a variant.

FIG. 13 is a view of an example arrangement of optical fibers.

FIG. 14 is a schematic view of a photoelectron source according to a variant.

### DETAILED DESCRIPTION

In one embodiment, a photoelectron source includes a photocathode supported on a surface side of a substrate, a light source emitting excitation light from a back surface side of the substrate, and a reflecting mirror disposed at a position opposed to the photocathode on the surface side of the substrate configured to reflect and focus the excitation light which has passed through the substrate to the photocathode and include an extraction hole through which photoelectrons emitted from the photocathode pass when the excitation light is incident on the photocathode.

Hereinafter, an embodiment of the present invention will be described based on the drawings.

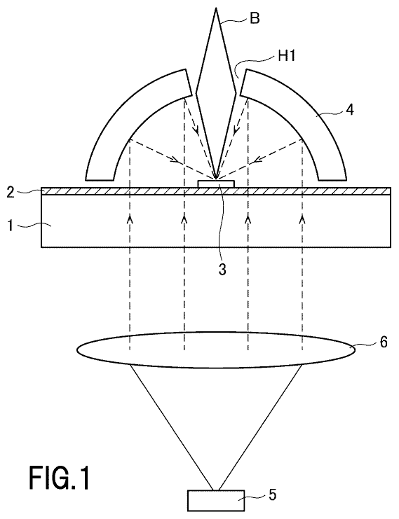

As illustrated in FIG. 1, the photoelectron source according to the present embodiment includes a glass substrate 1, a conductive film 2 formed on one surface of the glass substrate 1, a photocathode 3 provided on the conductive film 2, a focusing mirror 4 (reflecting mirror), a light source 5 and a lens 6. In the present embodiment, for the glass substrate 1, the conductive film 2 and the photocathode 3, the lower surfaces thereof in FIG. 1 are referred to as the back surfaces, and the upper surfaces thereof are referred to as the surfaces (front surfaces). In other words, the conductive film 2 is formed on the surface of the glass substrate 1. The photocathode 3 is formed on the surface of the conductive film 2. The back surface of the photocathode 3 is in contact with the surface of the conductive film 2.

The focusing mirror 4 is disposed at a position on the surface side of the glass substrate 1, and opposed to the photocathode 3. The light source 5 and the lens 6 are disposed on the back surface side of the glass substrate 1.

The glass substrate 1 is a substrate which allows excitation light to penetrate therethrough, and is made of synthetic quartz or sapphire glass. The glass substrate 1 is used as a partition window that partitions into e.g., a space that maintains a vacuum, and a non-vacuum space so that light can penetrate through the partition window. Also, in the example of FIG. 1, if necessary, an anti-reflection film for excitation light is coated on the surface of the glass material through which excitation light penetrates.

The conductive film 2 has an antistatic function, is transparent, and allows excitation light to penetrate therethrough. For example, an SnGeO film can be used as the conductive film 2.

When excitation light is incident on the photocathode 3, it emits photoelectrons. As the material for the photocathode 3, Au, diamond, LaB₆, low work function metal, and semiconductor such as GaN can be used. The thickness of the photocathode 3 is sufficiently larger than the penetration depth of the excitation light, and is approximately e.g., 1 μm.

The light source 5 generates a laser beam (excitation light). For example, the light source 5 generates ultraviolet light with a wavelength of 260 to 280 nm as the laser beam. The light source 5 is not limited to the laser light source, and may be another light source such as an LED or a lamp. The light source 5 may have a beam expander or the like.

The lens 6 is e.g., a convex lens. The laser beam generated by the light source 5 enters the lens 6 to be refracted, travels parallel to the optical axis, penetrates through the glass substrate 1 and the conductive film 2 to be incident on the focusing mirror 4.

The focusing mirror 4 is a concave mirror, and reflects and focuses the incident laser beam (parallel light flux) to the surface of the photocathode 3. For example, a silicon substrate can be used for the focusing mirror 4, the silicon substrate having a reflective surface for the laser beam, coated with aluminum, rhodium or ruthenium.

A potential that is positive relative to the photocathode 3 is applied to the focusing mirror 4 from a power supply which is not illustrated, and the focusing mirror 4 generates an electric field for the photocathode 3 in a direction to extract electrons, and serves as a photoelectron extraction electrode. The focusing mirror 4 has extraction hole H1 through which photoelectrons pass.

When the laser beam reflected by the focusing mirror 4 is incident on the photocathode 3, it generates photoelectrons. The generated photoelectrons are extracted from the surface of the photocathode 3 to the focusing mirror 4 by a positive potential applied to the focusing mirror 4. The photoelectrons pass through the extraction hole H1 of the focusing mirror 4, thus an electron beam B is emitted.

In the photoelectron source, excitation light is incident on the surface of the photocathode 3, and photoelectrons are extracted from the surface, thus the photocathode 3 is not required to be thin, and the excitation light can be utilized efficiently. In addition, because the excitation light is collected after passing through the glass substrate, it is possible to prevent reduction in excitation light transmission rate due to an occurrence of a defect which occurs when the glass substrate is irradiated with high-intensity ultraviolet light. Since the excitation light irradiation mechanism (the light source 5 and the lens 6) is disposed on the back surface side of the photocathode 3, implementation of multi-beam is easier as compared to when the irradiation mechanism is disposed on the surface side.

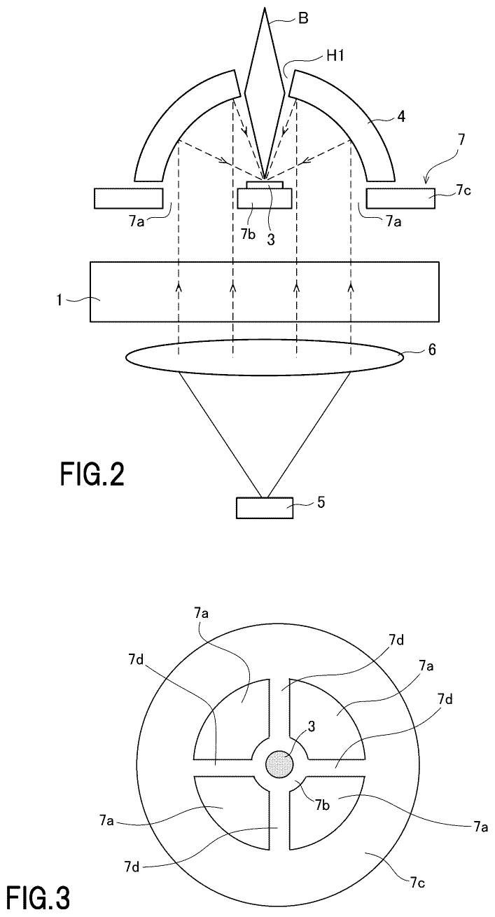

FIG. 2 is a schematic configuration view of a photoelectron source according to another embodiment. The same components as in the embodiment illustrated in FIG. 1 are labeled with the same reference numbers, and a description is omitted. In the photoelectron source illustrated in FIG. 2, the conductive film 2 is omitted from the photoelectron source illustrated in FIG. 1, support plate 7 is disposed on the surface side of the glass substrate 1 separated from the glass substrate 1, and the photocathode 3 is formed on the surface of the support plate 7.

The support plate 7 is a plate having a light shielding property, and comprised of e.g., a silicon substrate. The support plate 7 has openings 7a which allow a laser beam to pass therethrough, in the area other than installation site 7b for the photocathode 3. For example, as illustrated in FIG. 3, the openings 7a are formed so as to surround the installation site 7b for the photocathode 3, and structural portion 7c radially outward of the openings 7a, and the installation site 7b for the photocathode 3 are connected by a plurality of beams 7d to support the installation site 7b. In the example of FIG. 3, symmetrically arranged (arranged with a 90° interval) four beams 7d are provided.

The laser beam generated from the light source 5 is refracted by the lens 6 to become parallel to the optical axis, penetrates through the glass substrate 1, and passes through the openings 7a of the support plate 7 to be incident on the focusing mirror 4. The laser beam reflected by the focusing mirror 4 is focused and incident on the photocathode 3, and generated photoelectrons pass through the extraction hole H1 of the focusing mirror 4, thus the electron beam B is emitted.

In this photoelectron source, as in the photoelectron source illustrated in FIG. 1, excitation light is incident on the surface of the photocathode 3, and photoelectrons are extracted from the surface, thus the photocathode 3 is not required to be thin, and the excitation light can be utilized efficiently. Because the excitation light irradiation mechanism (the light source 5 and the lens 6) is disposed on the back surface side of the photocathode 3, implementation of multi-beam is facilitated.

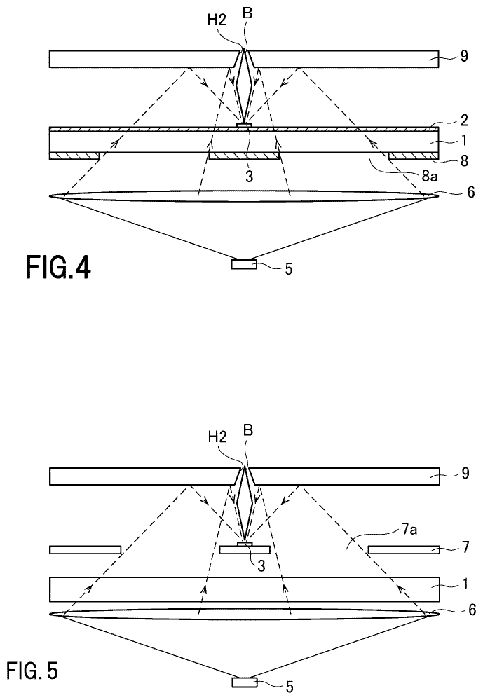

FIG. 4 is a schematic configuration view of a photoelectron source according to another embodiment. The same components as in the embodiment illustrated in FIG. 1 are labeled with the same reference numbers, and a description is omitted. The photoelectron source illustrated in FIG. 4 differs from the photoelectron source illustrated in FIG. 1 in that reflecting mirror 9 as a plane mirror is installed instead of the focusing mirror 4, and light shielding film 8 is formed on the back surface of the glass substrate 1.

A silicon substrate can be used for the reflecting mirror 9, the silicon substrate having a reflective surface (back surface) for the laser beam, coated with aluminum, rhodium or ruthenium.

A potential that is positive relative to the photocathode 3 is applied to the reflecting mirror 9 from a power supply which is not illustrated, and the reflecting mirror 9 serves as a photoelectron extraction electrode. The reflecting mirror 9 has extraction hole H2 through which photoelectrons pass.

The light shielding film 8 is e.g., a chromium film. The light shielding film 8 has opening 8a for laser beam passage. The opening 8a is formed so that the laser beam from the light source 5 does not reach the extraction hole H2 (does not pass through the extraction hole H2) of the reflecting mirror 9.

The laser beam generated from the light source 5 is refracted by the lens 6 to become focused light, passes through the opening 8a of the light shielding film 8, penetrates through the glass substrate 1 and the conductive film 2 to be reflected by the reflecting mirror 9, and is focused and incident on the surface of the photocathode 3. The photoelectrons generated by the laser beam incident on the photocathode 3 pass through the extraction hole H2 of the reflecting mirror 9, then the electron beam B is emitted.

In this photoelectron source, as in the photoelectron source illustrated in FIG. 1, excitation light is incident on the surface of the photocathode 3, and photoelectrons are extracted from the surface, thus the photocathode 3 is not required to be thin, and the excitation light can be utilized efficiently. Because the excitation light irradiation mechanism (the light source 5 and the lens 6) is disposed on the back surface side of the photocathode 3, implementation of multi-beam is facilitated. Because the reflecting mirror 9 is a plane mirror, as compared to when a concave mirror is utilized, production of the photoelectron source is facilitated.

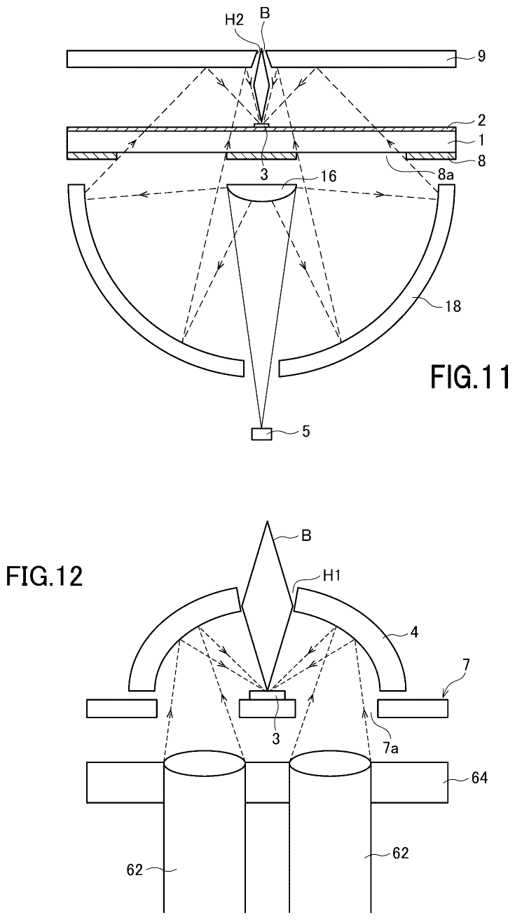

In the configuration illustrated in FIG. 4, the laser beam is refracted by the lens 6; however, as illustrated in FIG. 11, a light collection mirror set combining a convex mirror 16 and a concave mirror 18 may be used instead of the lens 6. The laser beam generated from the light source 5 is reflected by the convex mirror 16 and spreads, then reflected by the concave mirror 18 to become focused light, and passes through the opening 8a of the light shielding film 8.

FIG. 5 is a schematic configuration view of a photoelectron source according to another embodiment. The same components as in the embodiment illustrated in FIG. 2 are labeled with the same reference numbers, and a description is omitted. The photoelectron source illustrated in FIG. 5 differs from the photoelectron source illustrated in FIG. 2 in that the reflecting mirror 9 as a plane mirror is installed instead of the focusing mirror 4.

A silicon substrate can be used for the reflecting mirror 9, the silicon substrate having a reflective surface (back surface) for the laser beam, coated with aluminum, rhodium or ruthenium.

A potential that is positive relative to the photocathode 3 is applied to the reflecting mirror 9 from a power supply which is not illustrated, and the reflecting mirror 9 serves as a photoelectron extraction electrode. The reflecting mirror 9 has the extraction hole H2 through which photoelectrons pass.

The openings 7a of the support plate 7 are formed so that the laser beam from the light source 5 does not reach the extraction hole H2 of the reflecting mirror 9.

The laser beam generated from the light source 5 is refracted by the lens 6 to become focused light, penetrates through the glass substrate 1, passes through the openings 7a of the support plate 7 to be reflected by the reflecting mirror 9, and is focused and incident on the surface of the photocathode 3. The photoelectrons generated by the laser beam incident on the photocathode 3 pass through the extraction hole H2 of the reflecting mirror 9, then the electron beam B is emitted.

Also, in the configuration illustrated in FIG. 5, the light collection mirror set (see FIG. 11) combining the convex mirror 16 and the concave mirror 18 can be used instead of the lens 6.

In this photoelectron source, as in the photoelectron source illustrated in FIG. 2, excitation light is incident on the surface of the photocathode 3, and photoelectrons are extracted from the surface, thus the photocathode 3 is not required to be thin, and the excitation light can be utilized efficiently. Because the excitation light irradiation mechanism (the light source 5 and the lens 6) is disposed on the back surface side of the photocathode 3, implementation of multi-beam is facilitated. Because the reflecting mirror 9 is a plane mirror, as compared to when a concave mirror is utilized, production of the photoelectron source is facilitated.

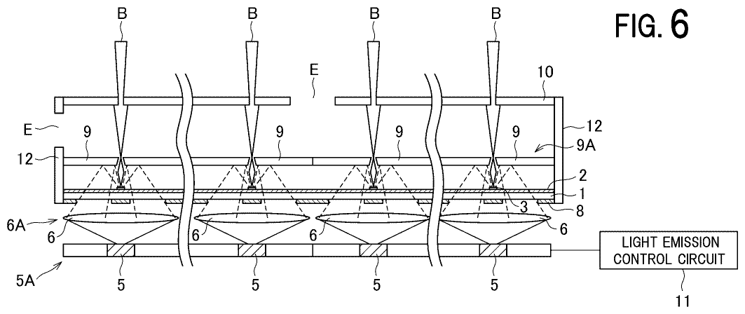

FIG. 6 is a schematic configuration view of a multi-photoelectron source that generates a multi-beam using multiple units of the photoelectron source illustrated in FIG. 4.

The multi-photoelectron source includes a light source array 5A, a lens array 6A, a glass substrate 1, a conductive film 2, a photocathode 3, a light shielding film 8, a reflecting mirror array 9A and an angle limiting aperture array substrate 10. The glass substrate 1, the reflecting mirror array 9A and the angle limiting aperture array substrate 10 are held by a peripheral wall portion 12.

The light source array 5A includes a plurality of light sources 5 arranged in an array pattern, and for example, an LED array can be used. The light emission ON/OFF of each of the plurality of light sources 5 of the light source array 5A is controlled by a light emission control circuit 11. Alternatively, a laser diode (LD) array may be used as the light source array 5A.

The lens array 6A has a plurality of lenses 6 corresponding to the plurality of light sources 5 of the light source array 5A. The reflecting mirror array 9A has a plurality of reflecting mirrors 9 corresponding to the plurality of light sources 5 of the light source array 5A.

The angle limiting aperture array substrate 10 is disposed downstream of the reflecting mirror array 9A in a beam travelling direction. The angle limiting aperture array substrate 10 has a plurality of apertures (openings) that limit the divergence angle of the electron beam emitted through the extraction hole of each reflecting mirror 9 of the reflecting mirror array 9A. As the material for the angle limiting aperture array substrate 10, for example, tantalum may be used.

In other words, the lenses 6, the photocathodes 3, the reflecting mirrors 9 and the angle limiting apertures are provided so as to correspond to the light sources 5 of the light source array 5A.

The excitation light generated from a light source 5 of the light source array 5A is refracted by a corresponding lens 6 of the lens array 6A to become focused light, passes through an opening of the light shielding film 8, penetrates through the glass substrate 1 and the conductive film 2 to be reflected by a reflecting mirror 9, and is focused and incident on the surface of a photocathode 3. The photoelectrons generated by the laser beam incident on the photocathode 3 pass through the extraction hole of the reflecting mirror 9, then the electron beam B is emitted.

The beam divergence angle of the electron beam B is limited by the angle limiting aperture array substrate 10. Consequently, electrons emitted with a large angle can be prevented and the emission angle between beams can be made uniform, thus blur variation of the beam (light source image to be formed) due to the aberration of a downstream lens system can be reduced.

The electron beam B is emitted from a plurality of photocathodes 3, and a multi-beam thereby can be formed. In addition, the current distribution of the multi-beam can be controlled by controlling the light emission intensity of each light source 5 with the light emission control circuit 11. For example, when the photoelectric generation efficiencies are not equal in the photocathodes that generate the beams in the multi-beam, the currents of the beams can be controlled to be the same by controlling the light emission intensity. Conversely, the distribution of the light emission intensity can be controlled so as to obtain a desired current distribution.

Opening E for vacuum exhaustion may be provided at the peripheral wall portion 12 between the reflecting mirror array 9A and the angle limiting aperture array substrate 10, or at a position sufficiently away from the aperture of the angle limiting aperture array substrate 10.

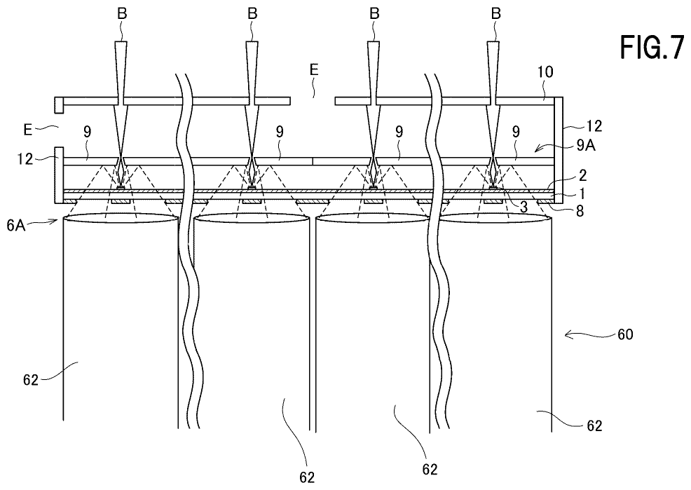

In the multi-photoelectron source, as illustrated in FIG. 7, excitation light may be guided to each lens of the lens array 6A through optical fiber bundle 60 in which a plurality of optical fibers 62 are bundled.

In FIG. 6, a multi-photoelectron source using multiple units of the photoelectron source illustrated in FIG. 4 has been described; however, a multi-photoelectron source may use multiple units of the photoelectron source illustrated in FIG. 1, FIG. 2 or FIG. 5.

The multi-photoelectron source is applicable to a multi-beam irradiation apparatus such as a multi-beam writing apparatus and a multi-beam inspection apparatus.

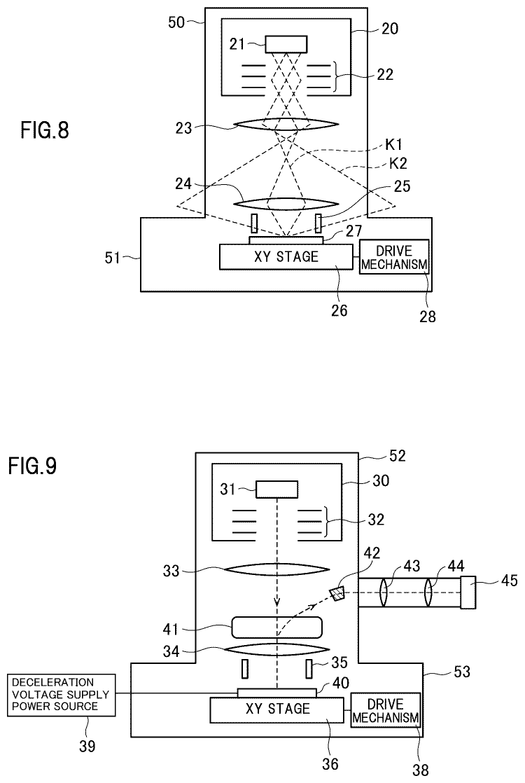

FIG. 8 illustrates a configuration example of a multi-beam writing apparatus. The multi-beam writing apparatus includes a column 50 and a writing chamber 51, and an inside of the column 50 and the writing chamber 51 is evacuated by a vacuum pump which is not illustrated.

In the column 50, an accelerating-focusing block 20, multi-stage electromagnetic lenses 23, 24, and a deflector 25 are disposed. In the accelerating-focusing block 20, multi-photoelectron source 21 and accelerating electrode group 22 are disposed.

In the writing chamber 51, an XY stage 26 is disposed, on which a sample 27 is placed, such as a mask blank coated with resist, the mask blank serving as a writing target substrate. The XY stage 26 is movable in the XY direction by drive mechanism 28.

The multi-photoelectron source 21 has a similar configuration to that of the multi-photoelectron source illustrated in FIG. 6. The light source array 5A and the lens array 6A illustrated in FIG. 6 are disposed outside the vacuum column 50.

The multi-beam emitted from the multi-photoelectron source 21 is accelerated by the accelerating electrode group 22, and is formed as a pattern image with a desired reduction factor on the sample surface by the electromagnetic lenses 23, 24. The dashed lines in FIG. 8 indicate on-axis trajectory K1 and off-axis trajectory K2. The entire multi-beam is collectively deflected by the deflector 25 in the same direction, and applied to respective irradiation positions of the beams on the sample 27. When the XY stage 26 is continuously moved, the irradiation position of each beam is controlled by the deflector 25 so that the irradiation position follows the movement of the XY stage 26.

When a desired pattern is written to the sample 27, the light emission control circuit 11 (see FIG. 6) performs control to turn off light emission of a light source corresponding to an unnecessary beam.

FIG. 9 illustrates a configuration example of a multi-beam inspection apparatus. The multi-beam inspection apparatus includes column 52 and inspection chamber 53, and an inside of the column 52 and the inspection chamber 53 is evacuated by a vacuum pump which is not illustrated.

In the column 52, an accelerating-focusing block 30, multi-stage electromagnetic lenses 33, 34, a deflector 35, a beam separator 41, a deflector 42, projection lenses 43, 44, and a multi-detector 45 are disposed. In the accelerating-focusing block 30, multi-photoelectron source 31 and accelerating electrode group 32 are disposed.

In the inspection chamber 53, XY stage 36 is disposed, on which substrate 40 as an inspection target is placed. The substrate 40 is a semiconductor substrate, a chip on which a pattern is formed, or a mask for forming a pattern. The XY stage 36 is movable in the XY direction by drive mechanism 38.

The multi-photoelectron source 31 has a similar configuration to that of the multi-photoelectron source illustrated in FIG. 6. The light source array 5A and the lens array 6A illustrated in FIG. 6 are disposed outside the vacuum column 52.

The multi-beam (multi-primary electron beam) emitted from the multi-photoelectron source 31 is accelerated by the accelerating electrode group 32, and is formed as a pattern image with a desired reduction factor on the substrate 40 by the electromagnetic lenses 33, 34. The entire multi-beam is collectively deflected by the deflector 35 in the same direction, and applied to respective irradiation positions of the beams on the substrate 40. When the XY stage 36 is continuously moved, the irradiation position of each beam is controlled by the deflector 35 so that the irradiation position follows (tracking deflection) the movement of the XY stage 36.

Note that a retarding voltage is applied to the substrate 40 by deceleration voltage supply power source 39, and the multi-primary electron beam is decelerated immediately before the substrate 40.

Due to irradiation of a desired position on the substrate 40 with the multi-primary electron beam, a bundle (multi-secondary electron beam) of secondary electrons including reflected electrons corresponding to the beams in the multi-primary electron beam is emitted from the substrate 40.

The multi-secondary electron beam emitted from the substrate 40 travels to the beam separator 41. The beam separator 41 generates an electric field and a magnetic field in orthogonal directions on a plane perpendicular to the direction (optical axis) in which the multi-primary electron beam travels. The electric field exerts a force in the same direction regardless of the traveling direction of electrons. In contrast, the magnetic field exerts a force according to Fleming's left-hand rule. Thus, the direction of the force acted on electrons can be changed depending on the direction of incoming electrons. For the multi-primary electron beam which enters the beam separator 41 from the upper side, the force caused by the electric field and the force caused by the magnetic field cancel each other, thus the multi-primary electron beam moves straight downward. In contrast, for the multi-secondary electron beam which enters the beam separator 41 from the lower side, both the force caused by the electric field and the force caused by the magnetic field are applied in the same direction, thus the multi-secondary electron beam is bent diagonally upward.

The multi-secondary electron beam bent diagonally upward is refracted by the projection lenses 43 and 44, and projected onto the multi-detector 45. The multi-detector 45 detects the projected multi-secondary electron beam. The multi-detector 45 has a plurality of detection pixels. The multi-detector 45 has e.g., a diode type two-dimensional sensor which is not illustrated. At diode type two-dimensional sensor positions corresponding to the beams in the multi-secondary electron beam, the secondary electrons in the multi-secondary electron beam collide with the diode type two-dimensional sensors, and secondary electron image data is generated for each pixel.

Since scanning is performed while continuously moving the XY stage 36, tracking deflection is performed as described above. According to the movement of the deflection position associated with the tracking deflection, the deflector 42 deflects the multi-secondary electron beam to be applied to a desired position on the light-receiving surface of the multi-detector 45.

The detection data (measurement images) of the secondary electrons detected by the multi-detector 45 is compared with reference images based on design pattern data, and the presence or absence of defect is determined.

In the above embodiment, in order to remove dirt (contamination) of the photocathode 3, a cleaning gas may be introduced, or a heating mechanism may be provided. The cleaning gas can be used, for example, by exciting hydrogen gas to generate atomic hydrogen.

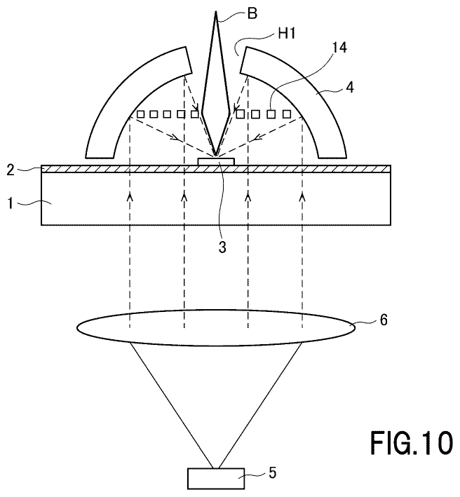

FIG. 10 shows a photoelectron source according to a modification. The configuration illustrated in FIG. 10 differs from the configuration illustrated in FIG. 1 in that grid electrode 14 having an aperture ratio with respect to excitation light is provided between the focusing mirror 4, and the photocathode 3, the glass substrate 1. Instead of using the focusing mirror 4 as an extraction electrode, a positive potential relative to the photocathode 3 is applied to the grid electrode 14 to extract photoelectrons. Normally, in the configuration illustrated in FIG. 10, a positive potential relative to the photocathode 3 is applied to the focusing mirror 4. When photoelectrons are not extracted, the potential of the grid electrode 14 relative to the photocathode 3 is set to the same potential or a negative potential. Since part of the excitation light is shielded by the grid electrode 14 in the configuration illustrated in FIG. 10, the utilization efficiency of the excitation light is lower than that in the configuration of FIG. 1; however, the shape of the grid electrode 14 and the shape of the focusing mirror 4 can be independently determined, thus respective shapes can be optimized from the viewpoint of extraction of photoelectrons and collection of the excitation light. The grid electrode 14 has an electrostatic shielding effect, thus even when an insulating material is used for the focusing mirror 4, and the focusing mirror surface is charged with electricity, the effect on the extraction of photoelectrons can be reduced.

In the above embodiment, the configuration has been described in which excitation light generated from one light source is incident on one photocathode; however, excitation light generated from a plurality of light sources may be incident on one photocathode so that the intensity of the excitation light incident on the photocathode may be allowed to be adjusted.

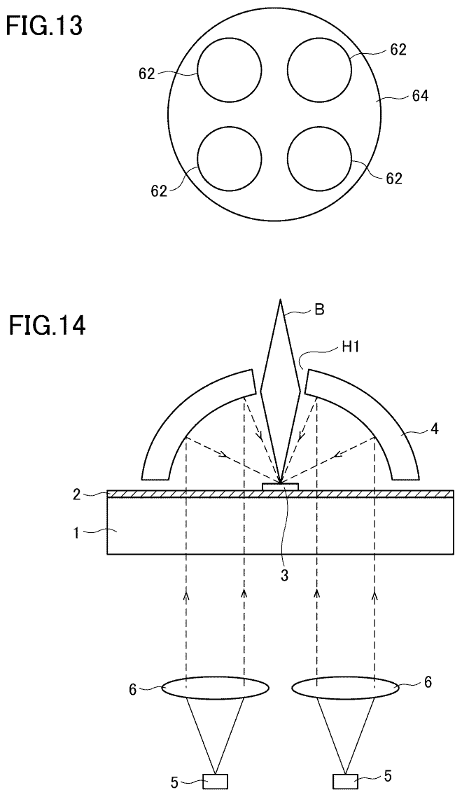

FIG. 12 shows a configuration in which the excitation light passing through a plurality of optical fibers 62 is incident on the photocathode 3 of the photoelectron source illustrated in FIG. 2. For example, as illustrated in FIG. 13, the excitation light passing through four optical fibers 62 supported by support plate 64 is incident on one photocathode 3. Each of the four optical fibers 62 is connected to a light source capable of independently controlling the light intensity, thereby controlling the intensity of the excitation light incident on the photocathode 3. The intensity of the excitation light incident on the photocathode 3 can be controlled in five levels by ON/OFF control of each of the light sources connected to the four optical fibers 62. In addition, further fine control is possible by adjusting the intensity of each light source.

FIG. 14 shows a configuration in which the excitation light from a plurality of (e.g., four) light sources 5 is incident on the photocathode 3 of the photoelectron source illustrated in FIG. 1. The intensity of the excitation light incident on the photocathode 3 can be controlled in multiple levels by independently controlling the output of the plurality of light sources 5.

Note that the present invention is not limited to the above embodiment as it is, and in an implementation phase, the components can be modified and implemented in a range not departing from the gist. For example, instead of controlling the excitation light output, the excitation light output may be maintained at substantially constant, and a blanker, and a blanking array for controlling the presence/absence of arrival of the electron beam to the sample surface may be provided downstream of the electron source so that the presence/absence of arrival of the electron beam to the sample surface and distribution of the multi-beam can be controlled at high speed.

Instead of applying a constant positive potential to the electrode, a positive potential may be applied to the electrode when beams are extracted, and the same potential or a negative potential may be applied to the electrode when beams are not extracted. When ON/OFF of each beam in the multi-beam is independently controlled, the resistance between adjacent electrodes can be set sufficiently high so that each electrode can be independently controlled. Conversely, when beams are extracted, the potential of the photocathode relative to the electrode can be controlled to be negative relative to the electrode. When photoelectrons are not extracted, the same potential or a negative potential relative to the electrode is applied.

An example has been presented in which the photocathode is implemented by forming a film; however, a thin film may be bonded or a bulk material may be used.

Various inventions can be formed by combining the plurality of components disclosed in the above embodiments as appropriate. For example, some components may be deleted from all components shown in the embodiments. Furthermore, components across different embodiments may be combined as appropriate.

What is claimed is:

1. A photoelectron source comprising:
a photocathode supported on a surface side of a substrate;
a light source emitting excitation light from a back surface side of the substrate; and
a reflecting mirror disposed at a position opposed to the photocathode on the surface side of the substrate configured to reflect and focus the excitation light which has passed through the substrate to the photocathode and include an extraction hole through which photoelectrons emitted from the photocathode pass when the excitation light is incident on the photocathode.

2. The photoelectron source according to claim 1,
wherein the reflecting mirror has an electrode function to extract the photoelectrons emitted from the photocathode to the extraction hole, and a positive potential relative to the photocathode is applied to the reflecting mirror.

3. The photoelectron source according to claim 1,
wherein the reflecting mirror is a concave mirror, and causes the excitation light to be focused on and applied to the photocathode.

4. The photoelectron source according to claim 3,
wherein the concave mirror includes a silicon substrate having a light reflective surface coated with aluminum, rhodium or ruthenium.

5. The photoelectron source according to claim 1,
wherein the reflecting mirror is a plane mirror, and provided with a lens or a light collection mirror set between the light source and the substrate, the lens or the light collection mirror being configured to cause the excitation light reflected by the plane mirror to be focused on the photocathode.

6. The photoelectron source according to claim 1,
wherein the substrate is transparent to the excitation light.

7. The photoelectron source according to claim 6, further comprising
a conductive film provided on the surface of the substrate, the conductive film allowing the excitation light to penetrate therethrough,
wherein the photocathode is provided on the conductive film,

8. The photoelectron source according to claim 7,
wherein the conductive film is an SnGeO film.

9. The photoelectron source according to claim 1, further comprising a support plate provided on the surface side of the substrate,
wherein the photocathode is provided on a side of the support plate opposite to the substrate.

10. The photoelectron source according to claim 9,
wherein an opening which allows the excitation light to pass therethrough is formed in the support plate, and the opening is formed in an area other than a portion where the photocathode is provided.

11. The photoelectron source according to claim 10,
wherein the support plate is a plate having a light shielding property.

12. The photoelectron source according to claim 1, further comprising
a plurality of light sources, each of which is the light source,
wherein the photocathode is irradiated with excitation light from the plurality of light sources.

13. The photoelectron source according to claim 12,
wherein an intensity of the excitation light from the plurality of light sources is independently controllable.

14. A multi-photoelectron source comprising
a plurality of photoelectron sources, each of which is the photoelectron source according to claim 1,
wherein a multi-electron beam is generated by photoelectrons which are respectively extracted through the extraction hole of the plurality of photoelectron sources.

15. The multi-photoelectron source according to claim 14, further comprising
an angle limiting aperture array substrate that includes apertures corresponding to beams in the multi-electron beam and that limits a divergence angle of an electron beam which passes through the apertures.

16. A multi-beam irradiation apparatus comprising:
the multi-photoelectron source according to claim 14; and
a stage on which a substrate is placed, the substrate to be irradiated with a multi-electron beam generated by the multi-photoelectron source.

17. A photoelectron source comprising:
a photocathode supported on a surface of a substrate;
a light source emitting excitation light from a back surface side of the substrate;
an electrode disposed at a position opposed to the photocathode on the surface side of the substrate configured to apply an electric field to the photocathode in a direction to extract electrons; and
a reflecting mirror including an extraction hole through which the photoelectrons extracted from the photocathode pass, and configured to reflect, to the photocathode, the excitation light which has passed through the substrate.
